(19) United States
(12) Patent Application Publication
(10) Pub. No.: US 2017/0142865 A1
(43) Pub. Date: May 18, 2017

(54) SLOTTED CONNECTOR

(71) Applicant: HEWLETT PACKARD ENTERPRISE DEVELOPMENT LP, Houston, TX (US)

(72) Inventors: Richard D GARRETT, Houston, TX (US); Arthur VOLKMANN, Houston, TX (US)

(21) Appl. No.: 15/323,729

(22) PCT Filed: Jul. 7, 2014
(86) PCT No.: PCT/US2014/045561

§ 371 Date: Jan. 3, 2017

(51) Int. Cl. H05K 7/20; H01R 12/70; H05K 7/14

(52) U.S. Cl. CPC H05K 7/20727; H05K 7/1487; H01R 12/7076

(57) ABSTRACT

A slotted connector apparatus can include a connector located between a first electronic component and a second electronic component, where the slotted connector comprises a first portion to be connected to the first electronic component and a second portion connected to the first portion and to be connected to the second electronic component. The second portion can include an integrated slot allowing airflow through the second portion of the connector.

### BACKGROUND

Connectors can be used to connect electronic components (e.g., server components, printed circuit boards, memory modules, etc.) within servers in a computing system or network to one another. Multiple portions (e.g., terminals) of the connector may be connected to an electronic component. The connector can transmit information (e.g., a signal) between the electronic components.

### BRIEF DESCRIPTION OF THE DRAWINGS

FIG. 1 illustrates a diagram of an example of an apparatus according to the present disclosure.

FIG. 2 illustrates a diagram of a schematic view of an example of an apparatus according to the present disclosure.

FIG. 3 illustrates a diagram of an example of a system according to the present disclosure.

FIG. 4 illustrates a diagram of an example of a system according to the present disclosure.

### DETAILED DESCRIPTION

Flexibility of electronic component placement has become important for next generation server designs and other high density applications. Some approaches to connecting these electronic components via a connector include using solid block-type connectors (e.g., array connectors) placed in locations not blocking airflow to downstream components. However, as bus speeds increase and routing distances decrease, solid block-type connectors have been placed in front of electronic components (e.g., banks of memory).

Placing connectors in front of electronic components may create a cooling dead zone and may limit the ability of fans to adequately cool electronic components downstream. This may lead to limitations on the type of electronic components a system can support downstream of connectors, the layout of electronic components in a system, and/or the flexibility of connector placement in a system.

In contrast, examples of the present disclosure allow for the inclusion of cooling slots also known as gaps, in connectors. This can reduce the impact of placing a connector in front of electronic components, as compared to other approaches, by allowing airflow (e.g., direct airflow) to electronic components, and in particular, to downstream electronic components.

Cooling slots added to connectors in accordance with the present disclosure can reduce the effect of placing a connector in front of electronic components. The resulting distributed air path can allow for greater airflow to cool electronic components downstream (e.g., directly downstream) as compared to other approaches. For instance, a connector in accordance with the present disclosure may be placed in front of banks of electronic components providing airflow targeted to specific electronic components within the bank. Loss of cooling capacity can be reduced when compared to the placement of a solid connector between banks of electronic components.

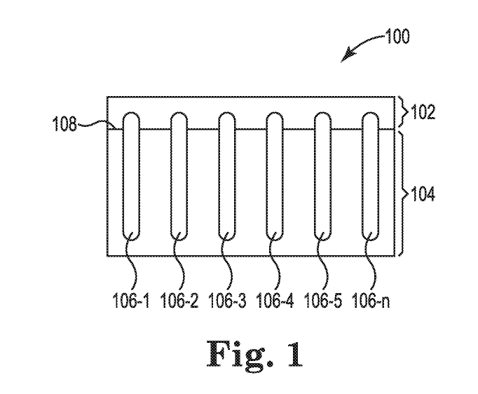

FIG. 1 illustrates a diagram of an example of an apparatus 100 according to the present disclosure. Apparatus 100 can be a connector between a plurality of electronic components in a number of examples. In some instances, connector 100 can be a high-speed connector. For instance, connector 100 can connect electronic components including memory modules and circuit boards, as well as other active, passive, an/or electromechanical electronic components. In a number of examples, electronic components can include server components, which can include electronic components located on or associated with a server or server blade, for instance.

Connector 100 can include a first portion 102 and a second portion 104. Portions 102 and 104 can also be referred to as mating portions, as they can be connected or “mated” to electronic components. Portions 102 and 104 may be separated, for instance, at separation line 108, should the connected electronic components be pulled apart. For instance, portion 102 may be connected to a first electronic component that is separated from a second electronic component connected to the portion 104. When separated, portion 102 stays connected to the first electronic component, while portion 104 stays connected to the second electronic component.

Slots 106-1, 106-2, . . . , 106-n can be included in connector 100 to allow for airflow to pass through the connector and downstream to electronic components. Slots 106-1, 106-2, . . . , 106-n can, in some instances, be located in just portion 104, just portion 102, or can be in both portions 102 and 104. In some examples, slots 106-1, 106-2, . . . , 106-n include gaps (e.g., air gaps) between groups of wafers inside of connector 100. For instance, electrical connections between a mezzanine card and a motherboard can be made on wafers inside of the connector (e.g., connector 100). These connections can be arranged in such a way that there are gaps between groups of wafers. These gaps, when used as cooling slots, (e.g., slots 106-1, 106-2, . . . , 106-n) can improve airflow through and around the connector. In addition, connector 100 including slots 106-1, 106-2, . . . , 106-n can have the same number of connections as a connector with no slots (e.g., solid block connector), for instance.

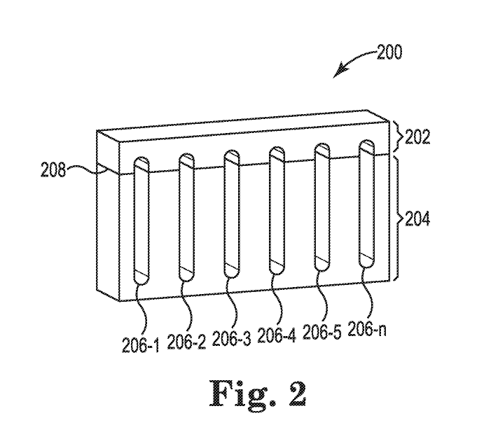

FIG. 2 illustrates a diagram of a schematic view of an example of an apparatus 200 according to the present disclosure. Similar to FIG. 1, connector 200 includes first portion 202, second portion 204, separation area 208, and slots 206-1, 206-2, . . . , 206-n. Slots 206-1, 206-2, . . . , 206-n can allow airflow through and around connector 200, allowing for better airflow to electronic components behind (e.g., downstream from) connector 200 as compared to solid block connectors. Also similar to FIG. 1, slots 206-1, 206-2, . . . , 206-n can include gaps between groups of wafers inside of connector 200.

In a number of examples, connector 200 can include a backplane connector. For instance, a connector within a backplane system can include slots (e.g., slots 206-1, 206-2, . . . , 206-n) allowing for airflow through and around the connector. One, two, or more of the connectors within the backplane system can include slots. In an example, a backplane system can be used as a backbone to connect printed circuit boards. At least one connector within the system can include slots (e.g., slots 206-1, 206-2, . . . , 206-n), which can increase the airflow to printed circuit boards located behind the connector, particularly in comparison to airflow to printed circuit boards behind a solid block connector. While used in this example, electronic components included in the backplane system are not limited to printed circuit boards. In addition, the backplane system may be active and/or passive.

Connector 200 can be a midplane connector in a number of examples. A midplane connector can include electronic components connected to both sides of the midplane connector. For instance, modules, cards, devices, and other electronic components can be connected to either side of a midplane connector. By implementing slots (e.g., slots 206-1, 206-2, . . . , 206-n) into a midplane connector, these modules, cards, devices, and other electronic components can receive better airflow, as compared to modules, cards, devices, and other electronic components connected to solid block connectors. Furthermore, electronic components downstream of the midplane connector can be exposed to increased airflow. In a number of examples, slotted backplane and midplane connectors in accordance with the present disclosure can prevent localized dead zones present with the use of solid block backplane and midplane connectors.

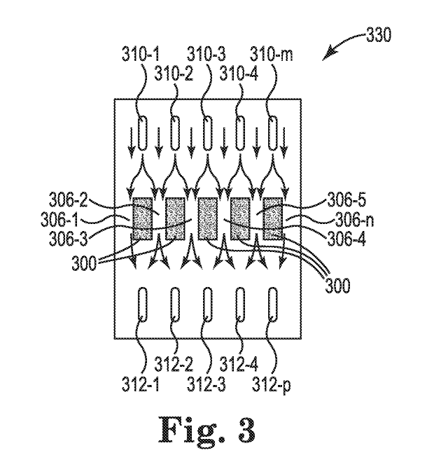

FIG. 3 illustrates a diagram of an example of a system 330 according to the present disclosure. In the example illustrated in FIG. 3, system 330 can include a connector 300 (e.g., midplane connector, backplane connector, server blade connector, etc.) including slots 306-1, 306-2, . . . , 306-n. FIG. 3, in some examples, is a cross-section of FIG. 1, for instance, cut across the middle of portion 104.

Airflow, illustrated by the arrows in FIG. 3, can move freely through and around connector 300 because of slots 306-1, 306-2, . . . , 306-n. For example, FIG. 3 illustrates a connector 300 between two banks of dual in-line memory modules (DIMMs). The first bank of DIMMs 310-1, 310-2, . . . , 310-m are connected to a printed circuit board within system 330 via a first set of connectors (e.g., different than connector 300), and the second bank of DIMMs (e.g., back-to-back or shadowed DIMMs) 312-1, 312-2, . . . , 312-p are connected to the printed circuit board via a second set of connectors (e.g., different from connector 300) Connector 300 can connect the printed circuit board to another electronic device, such as, for example, a daughter card, a mezzanine card, or a different printed circuit board, among others. Airflow to DIMMs 312-1, 312-2, . . . , 312-p (e.g., or other downstream electronic components) can be increased when connector 300 includes slots 306-1, 306-2, . . . , 306-n as compared to a solid block connector. In such an example, a solid block connector may not allow for enough airflow to a DIMM, which may create a substantial amount of heat. In other words, the solid block connector may result in a cooling dead zone. Slotted connector 300 can allow for a sufficient amount of airflow to reach DIMMs 312-1, 312-2, . . . , 312-p by creating an airflow path to the DIMM bodies, which can result in proper performance by the DIMM.

The example illustrated in FIG. 3 may include gaps between groups of wafers, which make up slots 306-1, 306-2, . . . , 306-n. For instance, system 330 and/or connector 300 may include 15 wafers. The 15 wafers may be divided into five sections of 3 wafers each (e.g., each portion 300 of the connector shown in FIG. 3), with the gaps between the sections making up slots 306-1, 306-2, . . . , 306-n. Examples of the present disclosure are not limited to a particular number of wafers, and the wafers need not be divided into equally numbered sections, for instance.

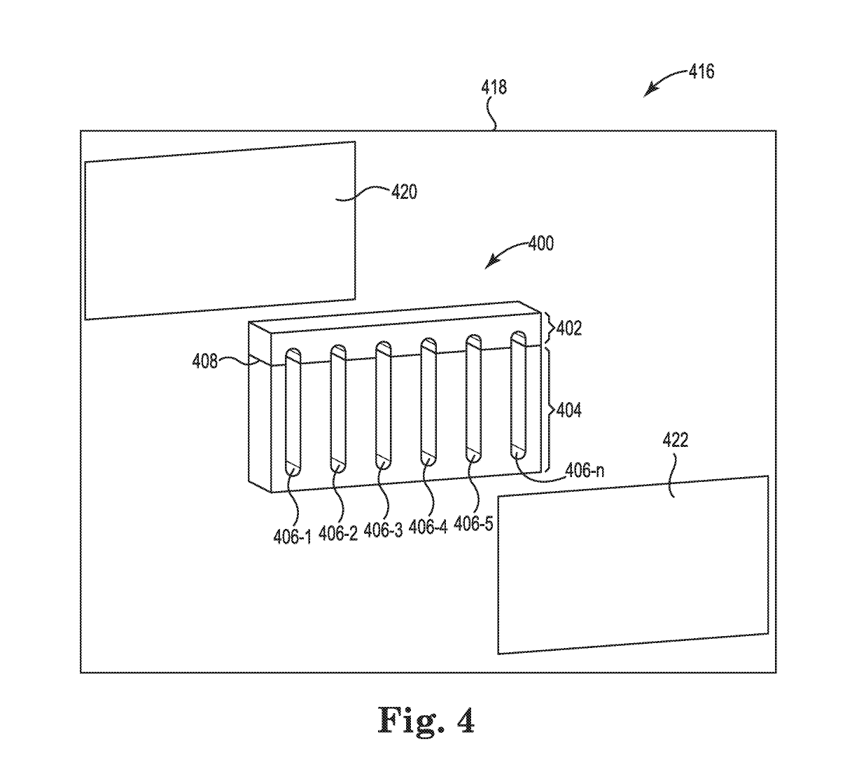

FIG. 4 illustrates a diagram of an example of a system 416 according to the present disclosure. System 416 includes electronic components 420 and 422 connected to server blade 418 and connected to one another via connector 400. While the example illustrated in FIG. 4 includes connector 400 within a server blade, in a number of examples, connector 400 can be located within a server chassis to route air from one location to another.

Connector 400 can include a first portion 402 that may be connected to electronic component 420, and second portion 404 that may be connected to electronic component 422. In such an example, should electronic component 420 be separated from electronic component 422, connector 400 may separate at 408. This would result in portion 402 remaining connected to electronic component 420, and portion 404 remaining connected to electronic component 422.

Connector 400 can include slots 406-1, 406-2, . . . , 406-n that allow airflow through and around connector 400. The airflow through and around connector 400 can allow for increased airflow to electronic components. For instance, in the example illustrated in FIG. 4, electronic components 420 and 422 are positioned such that air flowing through slots 406-1, 406-2, . . . , 406-n can reach either and/or both electronic components 420 and 422 with greater ease and efficiency than if connector 400 was a solid block connector. In some instances, connector 400 can be located directly in front of electronic component 422, and airflow can still pass to electronic component 422 because of slots 406-1, 406-2, . . . , 406-n. In contrast, an electronic component may receive reduced or no airflow in systems including solid block connectors located directly in front of the electronic component.

This increased airflow via slots 406-1, 406-2, . . . , 406-n in connector 400 can also result in a decrease in pressure drop within a server as compared to solid block connectors. For example, inserting an obstruction to airflow creates an increase in airflow pressure drop. By introducing slots 406-1, 406-2, . . . , 406-n into connector 400, the pressure drop across the connector is less than a similar sized connector without slots. A decrease in pressure drop results in fan power savings. Further, because airflow is increased, fan power consumption within system 416 (e.g., within server blade 418) can be reduced. Electronic component placement can be more flexible with a slotted connector (e.g., connector 400) as compared to solid block connectors, as airflow to electronic components located in different locations may be attainable because of the slotted connector. For instance, locations of electronic components within server blade 418 may be flexible, based on the location of slots 406-1, 406-2, . . . , 406-n (e.g., locations of gaps between wafers).

Connector 400 may also be less expensive to implement as compared to multiple solid block connectors arranged in a similar footprint. One connector may be slotted and installed, rather than installing multiple, small, discreet connectors in a similar footprint. In addition, maintaining one connector with slots, as opposed to multiple connectors can allow for maintenance of alignment, structural integrity, and speed characteristics, signal characteristics, and pin-to-pin characteristics of the connector (e.g., of the original connector). Connector 400 may also be more mechanically robust compared to the multiple connectors. For example, reducing the number of connectors in a server, system, etc. can reduce the risk of connector failure, and in turn, can result in an increase in mechanical robustness over a server, system, etc. using multiple connectors. In some instances, connector 400 may also have a smaller footprint than the multiple connectors, resulting in more flexibility and better airflow, among other benefits.

In the foregoing detailed description of the present disclosure, reference is made to the accompanying drawings that form a part hereof, and in which is shown by way of illustration how examples of the disclosure may be practiced. These examples are described in sufficient detail to enable those of ordinary skill in the art to practice the examples of this disclosure, and it is to be understood that other examples may be utilized and that process, electrical, and/or structural changes may be made without departing from the scope of the present disclosure.

The figures herein follow a numbering convention in which the first digit corresponds to the drawing figure number and the remaining digits identify an element or component in the drawing. Elements shown in the various figures herein can be added, exchanged, and/or eliminated so as to provide a number of additional examples of the present disclosure. In addition, the proportion and the relative scale of the elements provided in the figures are intended to illustrate the examples of the present disclosure, and should not be taken in a limiting sense. Further, as used herein, “a number of” an element and/or feature can refer to one or more of such elements and/or features.

What is claimed:

1. An apparatus, comprising:
a connector located between a first electronic component and a second electronic component, the connector comprising:
a first portion to be connected to the first electronic component; and
a second portion connected to the first portion and to be connected to the second electronic component,
wherein the second portion includes an integrated slot allowing airflow through the second portion of the connector.

2. The apparatus of claim 1, wherein the first portion and the second portion include the integrated slot, allowing airflow through the first portion and the second portion.

3. The apparatus of claim 1, wherein the connector is a mezzanine connector.

4. The apparatus of claim 1, wherein the integrated slot includes a gap between wafers inside of the connector.

5. The apparatus of claim 1, wherein at least one of the first and the second electronic components includes a dual in-line memory module (DIMM).

6. The apparatus of claim 1, wherein the connector is a backplane connector.

7. The apparatus of claim 1, wherein the connector is a midplane connector.

8. The apparatus of claim 1, wherein the first portion includes a mating portion mated to the first electronic component.

9. A system, comprising:
a server blade;
a plurality of electronic components connected to the server blade; and
a connector connecting at least two of the plurality of electronic components to one another and including a plurality of wafers arranged such that a gap exists between at least two of the plurality of wafers.

10. The system of claim 9, wherein the gap allows airflow to move through the gap and to one of the at least two of the plurality of electronic components connected by the connector.

11. The system of claim 9, wherein the connector is located directly in front of one of the at least two of the plurality of electronic components connected by the connector.

12. The system of claim 9, wherein locations of the plurality of electronic components is flexible, based on the location of the gap between the at least two of the plurality of wafers.

13. An apparatus, comprising:
a connector located between an electronic component and a bank of electronic components, wherein the bank of electronic components are downstream from the electronic component, and wherein the connector comprises:
a plurality of integrated slots to target particular electronic components within the bank of electronic components with airflow that moves through the plurality of integrated slots.

14. The apparatus of claim 13, wherein the particular electronic components include memory components.

15. The apparatus of claim 13, wherein the connector is located within a server chassis.
